(19) United States
(12) Patent Application Publication
(10) Pub. No.: US 2005/0164438 A1
(43) Pub. Date: Jul. 28, 2005

(54) Method for manufacturing a semiconductor device

(75) Inventors: Kensuke Okonogi, Tokyo (JP); Kiyonori Oyu, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/043,085

(22) Filed: Jan. 27, 2005

(30) Foreign Application Priority Data
Jan. 27, 2004 (JP) 2004-018034

(51) Int. Cl. H01L 21/336; H01L 21/8234; H01L 21/76

(52) U.S. Cl. 438/197; 438/306; 438/289

(57) ABSTRACT

A method for manufacturing a MOS transistors in a semiconductor device includes the step of implanting a dopant in a channel layer or source/drain regions by using a multi-step implantation and an associated multi-step heat treatment, wherein the multi-step implantation includes a number of steps of implantation each for implanting the dopant at a dosage lower than 1×10¹³/cm². The total dosage of the multi-step implantation ranges between 1×10¹³/cm² and 3×10¹³/cm².

### BACKGROUND OF THE INVENTION

1. Field of the Invention

The present invention relates to a method for manufacturing a semiconductor device, and more specifically, to a method for manufacturing a semiconductor device, which is suited to manufacture of the memory cells in DRAM devices, SRAM devices, and the like for use in mobile information terminals such as cellular phones.

2. Description of Related Art

Memory cells in DRAMs or SRAMs used in mobile information terminals especially require MOS transistors that cause a small junction leakage current. FIG. 10 shows the structure of a semiconductor device described in Patent Publication JP-A-2003-17586, as an example of a conventional semiconductor device.

In the semiconductor device 82, a plurality of MOS transistors arranged in the form of pairs of transistors which share a bit line 11 are formed on a semiconductor substrate 31, as shown in the figure. The semiconductor substrate 31 has shallow-trench isolation regions where an insulating film 12 is filled in shallow trenches, and active regions isolated from one another by the element isolation regions. The pair of transistors are formed in a single active region. Each active region is formed in a common p-type well layer 13 to which a substrate potential is applied, and has a p-type channel layer 14 which determines the threshold voltage of the transistors. An n-type buried well layer not shown is formed below the p-type well layer 13.

On both sides of the plug 15 connected to the bit line 11, there are two gate electrodes 16 each having side spacers 18. Each gate electrode 16 is formed on the p-type channel layer 14, with a gate insulating film 17 interposed therebetween. N-type lightly-doped diffused regions 19 each of which configures a source/drain diffused region are connected to the central plug 15 coupled to the bit line 11 and to other plugs 15 coupled to capacitors 20 through plugs 21. The plugs 15 are configured from a polysilicon film doped with phosphorous and fill the contact holes penetrating to the top surface of the p-type channel layer 14 from the top surface of an interlayer dielectric film 22.

In the semiconductor device 82 shown in FIG. 9, phosphorus is implanted to form an electric-field-alleviation layer 91 for the purpose of alleviating the electric fields, after forming the contact holes, in the process of forming the plugs 15. Implantation of phosphorus to alleviate electric fields is generally effected at a depthwise position deeper than the n-type lightly-doped diffused regions 19 as shown in the figure. This technique is described in Patent Publication JP-B-3212150, for example. Interlayer dielectric films 23 and 24, in which the bit line 11 and the plugs 21 are formed, are interposed between the plugs 15 along with the interlayer dielectric film 22 and the capacitors 20.

With respect to the method for manufacturing a semiconductor device, as shown in FIG. 10, a description will now be made particularly to a process from steps of forming the n-type buried well layer, p-type well layer 13 and p-type channel layer 14 up to the step of forming the n-type lightly-doped diffused regions 19. Subsequently to formation of element isolation regions, a silicon oxide film not shown is formed on the substrate surface. Next, phosphorus implantation is carried out at an acceleration energy of 1000 KeV and a dosage of 1×10¹³/cm², through the silicon oxide film, to form the n-type buried well layer (not shown) near the bottom of the p-type well layer 13. Through the silicon oxide film on the substrate surface, boron implantation is carried out four times at an acceleration energy of 300 keV and a dosage of 1×10¹³/cm², at an acceleration energy of 150 keV and a dosage of 5×10¹²/cm², at an acceleration energy of 50 keV and a dosage of 1×10¹²/cm², and at an acceleration energy of 10 keV and a dosage of 2×10¹²/cm², respectively. Although not specifically described in the Patent Publication JP-A-2003-17586, the implanted boron is diffused to form the p-type well layer 13 by performing a subsequent heat treatment at a substrate temperature of 1000° C., in general cases. Subsequently, boron implantation is carried out at an acceleration energy of 10 KeV and a dosage of 7×10¹²/cm², through the silicon oxide film on the substrate surface, to form the p-type channel layer 14.

Next, the silicon oxide film on the substrate surface is removed, and a gate oxide film is formed on the substrate surface by a thermal oxidation process. The boron implanted to form the channel layer 14 is redistributed by heat during the thermal oxidation. Subsequently, a material to form the gate electrodes 16 and an insulating film are consecutively deposited, followed by patterning thereof to form gate electrode structures.

Thereafter, the side surfaces of the gate electrodes 16 and the substrate surface are thermally oxidized. Then, using the gate electrode structure as a mask, phosphorus implantation is performed on the substrate surface, at an acceleration energy of 10 KeV and a dosage of 2×10¹³/cm². Subsequently, a heat treatment to diffuse the implanted phosphorus is carried out to thereby form the n-type lightly-doped diffused regions 19 which configure source/drain diffused regions. The heat treatment subsequent to the phosphorus implantation is carried out to serve also to diffuse a dopant which is implanted to form source/drain diffused regions for transistors in peripheral circuits, or else the heat treatment is carried out immediately after the phosphorus implantation. In any case, the heat treatment is effected in a nitrogen ambient at a substrate temperature of 900 to 1000° C. for several tens of seconds.

In recent years, miniaturization of the memory cells has been progressing more and more because of demands for higher integration of DRAMs. To achieve this miniaturization, the gate length has to be shortened while maintaining the threshold voltage of transistors. The dosage of the channel layer is raised in consistence therewith. Consequently, the junction electric field between the channel layer and the source/drain diffused regions becomes large, causing an increase in the junction leakage current which lowers the data retention characteristic of the memory cells. To reduce the junction leakage current, there are a method for alleviating electric field strength across the p-n junctions, and another method for reducing the number of crystal defects remaining in the source/drain diffused regions, which are the origins of the junction leakage current.

In order to prevent deterioration of the data retention characteristic of the memory cells, discussions have been made as to a variety of methods which would reduce the junction leakage current by means of alleviation of electric field strength across the p-n junctions for the source/drain diffused regions. For example, Patent Publication JP-B-3212150 proposes that impurity concentration (carrier density) distributions of p-type and n-type regions be set so that the electric field across the p-n junctions might not exceed 1 MV/cm, at which the local Zener effect generally becomes dominant. However, as further miniaturization of semiconductor devices has been proceeding, the method for reducing the junction leakage current by alleviating the electric field strength has come close to the upper limit of itself. Hence, much attention is paid to a method for reducing the number of crystal defects.

However, the impurity density in the channel layer has to be high in order to maintain a specific threshold voltage with a short gate length. The dosage of dopant implantation therefore has to be large. Consequently, the number of crystal defects caused by the dopant implantation are increased to cause an increase in the junction leakage current, thereby hindering improvements in the data retention characteristic of the memory cells.

In order to maintain a specific threshold voltage with a short gate length, a heat treatment for redistributing the dopant implanted to form source/drain diffused regions cannot be performed sufficiently. That is, if a heat treatment at a high temperature for a long time period, which is enough to remove the number of crystal defects, is carried out after implantation of a dopant, the implanted dopant diffuses so much that the effective channel length becomes short, resulting in a decrease in the threshold voltage. Therefore, the number of crystal defects cannot be reduced sufficiently, and thus, the junction leakage current caused by those defects cannot be effectively reduced.

### SUMMARY OF THE INVENTION

In view of the above, it is an of the present invention to provide a method for manufacturing a semiconductor device in which the junction leakage current caused by the number of crystal defects is reduced by reducing the number of crystal defects without performing a heat treatment at a high temperature for a long time period, thereby improving a data retention characteristic of the memory cells in a DRAM device or reducing the standby current in an SRAM device.

The present invention provides, in a first aspect thereof, a method for manufacturing a semiconductor device having a MOS transistor, including the step of: implanting a dopant in a specific region or specific layer at a dosage not lower than 1×10¹³/cm² by using a multi-step implantation and an associated multi-step heat treatment, the multi-step implantation including a number of steps of implantation each for implanting the dopant in the specific region or specific layer at a dosage lower than 1×10¹³/cm².

According to the first aspect of the present invention, each step of the multi-step implantation implanting the dopant at a dosage of 1×10¹³/cm² or less and an associated step of heat treatment are carried out until the total dosage of the dopant exceeds a needed dosage of 1×10¹³/cm² or higher, thereby reducing the number of residual crystal defects in the implanted region or layer. Therefore, the resultant semiconductor device has a reduced junction leakage current. As a result, it is possible to reduce the junction leakage current of the MOS transistor to improve the data retention characteristic of memory cells in a DRAM device or reducing the standby current of an SRAM device.

The present invention provides, in a second aspect thereof, a method for manufacturing a semiconductor device having a MOS transistor, including the step of: selecting boron having a mass number of 10 to implant a specific region or layer therewith.

According to the second aspect of the present invention, boron atoms having a mass number of 10 are selected to be implanted to the specific region or layer of the semiconductor substrate, so as to reduce the acceleration energy for implantation and the total mass of the atoms implanted. This reduces the damage in the crystal structure of the substrate caused by the implantation. As a result, the number of crystal defects remaining after the heat treatment are reduced, thereby providing a semiconductor device having a reduced junction leakage current. In a preferred embodiment of the second aspect of the invention, the specific region or layer is a channel layer.

### BRIEF DESCRIPTION OF THE DRAWINGS

FIGS. 1A to 1G are sectional views showing consecutive process steps in a method for manufacturing a semiconductor device, according to a first embodiment of the present invention.

FIG. 2 is a sectional view showing the final process step subsequent to the step of FIG. 1G.

FIG. 3 is a graph showing the relationship between the cumulative frequency and the data retention time in DRAM devices.

FIG. 4 is a sectional view showing the structure of a CMOS device manufactured by a method according to a second embodiment of the present invention.

FIGS. 5A to 5K are sectional views showing process steps in a method for manufacturing a semiconductor device, according to the second embodiment of the present invention.

FIG. 6 is a graph showing the relationship between the junction leakage current across an n+/p interface and a reverse-biased voltage applied thereto in n-channel MOS transistors.

FIG. 7 is a graph showing the relationship between the junction leakage current across a p+/n interface and a reverse-biased voltage applied thereto in p-channel MOS transistors.

FIG. 8 is a graph showing the relationship between the normalized number of residual defects and the normalized amount of the heat treatment.

FIG. 9 is a graph showing the relationship between the normalized number of residual defects and a number of steps of implantation.

FIG. 10 is a sectional view showing the structure of a conventional semiconductor device.

### DETAILED DESCRIPTION OF THE PREFERRED EMBODIMENTS

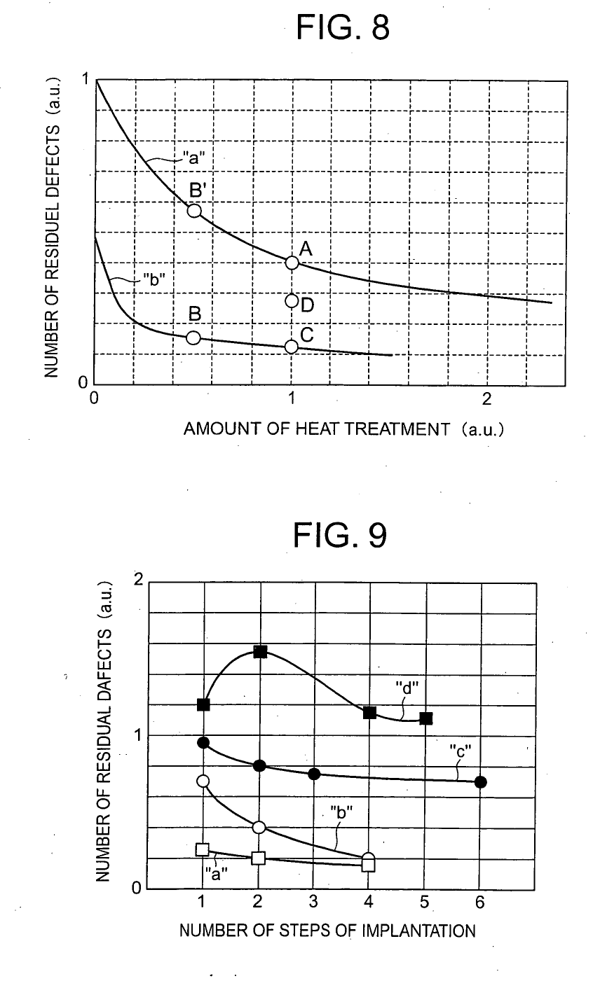

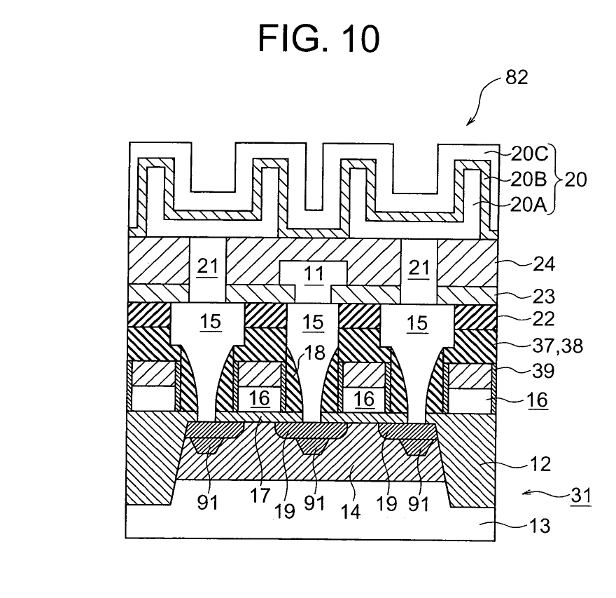

The present inventors conducted the following first and second experiments prior to the present invention. In the first experiments, a dopant of a predetermined dosage was implanted to a semiconductor substrate, and thereafter, a heat treatment for redistributing the dopant was carried out. An investigation was conducted as to the number of crystal defects remaining after the heat treatment, by obtaining the relationship between the number of residual defects and the amount of the heat treatment. The term “amount of heat treatment” used herein means an amount which is approximated to by a product of the time interval and the temperature for which and at which the heat treatment is conducted. The first experiments were conducted while changing the dosage at which the dopant was implanted. It was hence found that dependence of the number of defects remaining after the heat treatment upon the amount of the heat treatment varies depending on the dosage. FIG. 8 shows the relationship between the normalized number of residual defects and the normalized amount of the heat treatment, the relationship being obtained in case “a” where dopant implantation was conducted at a dosage needed to form a specific implanted region and in case “b” where dopant implantation was conducted at half the dosage needed to form the specific implanted region. From comparison of graphs “a” and “b”, it can be understood that the graph “b” indicative of the case of the smaller dosage in the dopant implantation resulted in a faster decrease in the number of residual defects, as plotted along with the amount of the heat treatment.

A consideration detailed below was then deduced from the above experimental results. The needed dosage for the specific region was employed for a single-step dopant implantation, such as conducted in a conventional method, and thereafter, a heat treatment to redistribute the dopant was carried out in an allowable amount of the heat treatment. The allowable amount of the heat treatment is herein defined as “1” or unit, and is used for normalizing other amounts of the heat treatments. In this case, the number of residual defects after the heat treatment using the allowable amount of hat treatment was indicated as the point A on the graph “a” in the figure.

For the graph “b”, the needed dosage is divided by two and each half of the needed dosage is employed in two steps of implantation, each step being followed by a subsequent heat treatment. The two-step implantation allows each step of the heat treatment to use an amount of 0.5 for the each step of the heat treatment for redistributing the dopant in an amount of 0.5. In a first implantation step, a dopant is implanted at a dosage which is ½ of the needed dosage, and thereafter, a first-step heat treatment was carried out. In this case, the number of residual defects is indicated at the point B on the graph “b” in the figure. The graph “b” shows a faster decrease of the residual defects in the lower range of the amount of heat treatment, as plotted along with the amount of heat treatment. Thus, the number of residual defects indicated at the point B is much less than ½ of the amount at the point B′ which indicates the number of residual defects when a heat treatment having a heat treatment amount of 0.5 was carried out after the needed dosage was used in the single-step implantation.

Subsequently, the dopant was again implanted in a second-step implantation at a dosage which is half the needed dosage, and thereafter, a subsequent second-step heat treatment is carried out in an amount of 0.5 for the heat treatment. In this case, the number of residual defects is indicated at the point C on the graph “b” in the figure, which is lowered further from the number of residual defects at the point B indicative of the residual defects after the first-step implantation and first-step heat treatment. These second-step implantation and second-step heat treatment caused new or additional residual defects equivalent to the number of residual defects indicated at the point B. Therefore, the number of residual defects after the second-step implantation and the second-step heat treatment is indicated at the point D which is approximated to by a sum of the numbers of residual defects indicated at the points B and C, and is thus smaller than the number of residual defects indicated at the point A attained in the case of a single-step implantation associated with a single-step heat treatment.

Thus, by dividing the dosage needed to form an implanted region by a number corresponding to the number of steps for the multi-step implantation, and by performing a multi-step heat treatment corresponding to the multi-step implantation, the number of residual defects can be reduced compared to the case of performing a single-step implantation associated with a single-step heat treatment. The effect of reducing the residual defects can be expected in any of the dopant implantation processes such as for forming a well layer, channel layer, pocket regions, and source/drain diffused regions in the semiconductor device. It is to be noted that, depending on the allowable dopant redistribution by a heat treatment, the allowable amount of heat treatment varies; therefore, the effect of reducing the residual defects varies.

Subsequently to the first experiments, the present inventors conducted second experiments to quantitatively investigate the range of dosage of phosphorus which has an effect of reduction on the number of residual defects by the multi-step implantation in the process of forming the source/drain diffused regions by phosphorus implantation. In the second experiments, the dosages of phosphorus needed to form source/drain diffused regions were assumed at 1×10¹³, 2×10¹³, 3×10¹³, and 4×10¹³/cm². In one case, implantation was performed in a single step for each of the needed dosages, and a single-step heat treatment was carried out after the implantation. In another case, implantation was performed in two or more steps for each of the needed dosages and associated a heat treatment for each of the steps of the multi-step implantation. The number of residual defects was examined in both cases. When any of the needed dosages was implanted in a single step, the subsequent heat treatment was carried out at a substrate temperature of 900 to 1000° C. for 1 to 60 seconds. When two- or more-step heat treatments were carried out, each step of the heat treatment was carried out in an amount, which is obtained by dividing the allowable amount of heat treatment allowable to redistribute the dopant by the number of steps.

FIG. 9 shows results of the second experiments. In this figure, the graphs “a”, “b”, “c” and “d” correspond to the results when the needed dosage were 1×10¹³/cm², 2×10¹³/cm², 3×10¹³/cm² and 4×10¹³/cm², respectively. From the results of the second experiments, it is found that the number of residual defects can be effectively reduced if the dosage in each step of the implantation is 1×10¹³/cm² or less so long as the needed dosage of phosphorus is within the range of 1×10¹³/cm² to 3×10¹³/cm². Particularly, if the reduction rate (%) of the number of residual defects after the first-step implantation and first-step heat treatment is taken as a reference, the maximum effect is obtained when the needed dosage is 2×10¹³/cm².

Although the effect can be obtained when the needed dosage is 3×10¹³/cm² or less, the effect cannot be substantially obtained when the needed dosage is 4×10¹³/cm² or above. If the two-step implantation is performed in case where the needed dosage is 4×10¹³/cm², defects which remain after the first-step implantation associated with the subsequent heat treatment will decrease. However, the second-step heat treatment subsequent to the second-step implantation is insufficient, and accordingly, the number of residual defects increases on the contrary. When the needed dosage is 1×10¹³/cm², the amount of generated crystal defects is originally small, and therefore, the effect obtained by the two-step implantation and two-step heat treatment is relatively small.

Further, the present inventors considered as follows. In the conventional boron implantation, boron having a mass number of 11 is selected and implanted, from the view point of work efficiency. Now assume another case of selecting and implanting boron having a mass number of 10. Then, the total mass of the dopant to be implanted is smaller by about 10% than in the conventional case of selecting boron having a mass number of 11. In addition, by employing a smaller mass by about 10%, the acceleration energy can be set lower also by about 10%. In general, the amount of energy deposition is considered to correspond to the amount of implantation damages by a dopant, and can be approximated to by the product of the acceleration energy and the total implanted mass. Therefore, implantation damages can be reduced by about 20% from the conventional case by selecting and implanting boron having a mass number of 10.

By reducing the implantation damages, the number of crystal defects remaining after the heat treatment can also be reduced, in general. The present inventors hence reached a concept of reducing the number of crystal defects by selecting and implanting boron having a mass number of 10. This kind of effect can be expected for all of boron-implanted regions or layers in a semiconductor device.

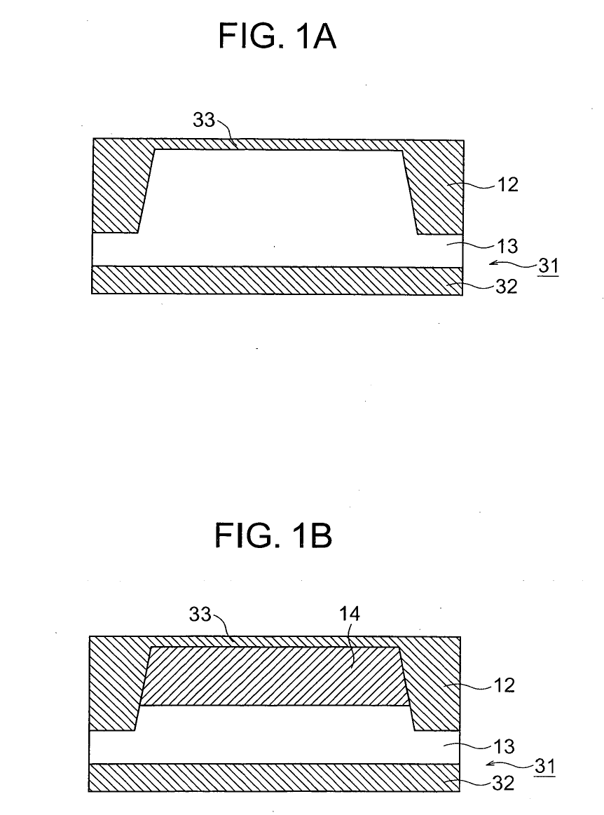

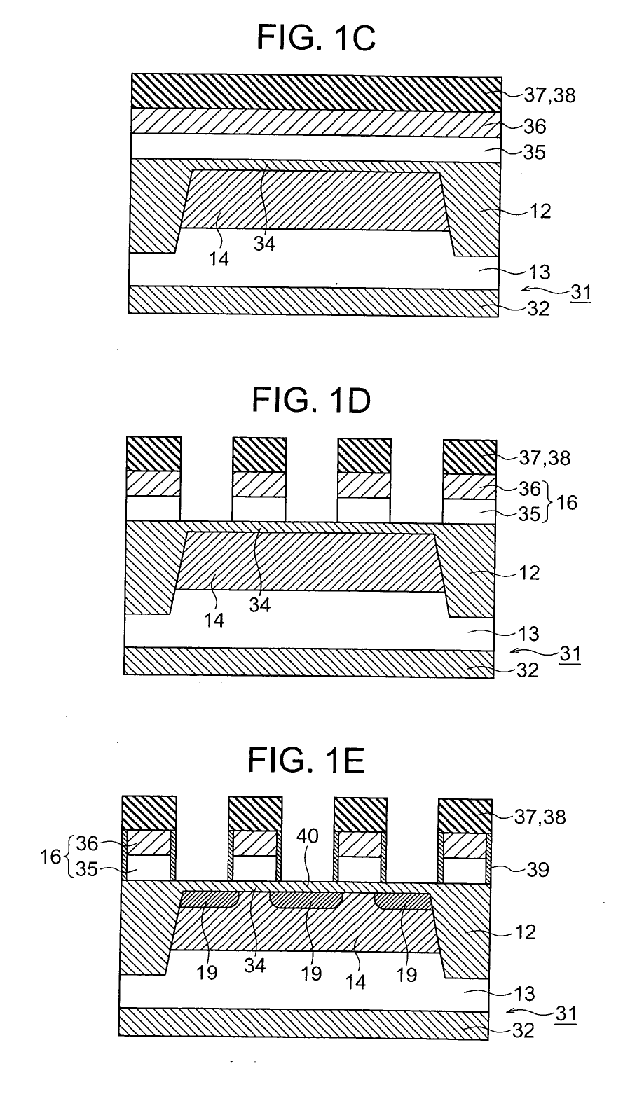

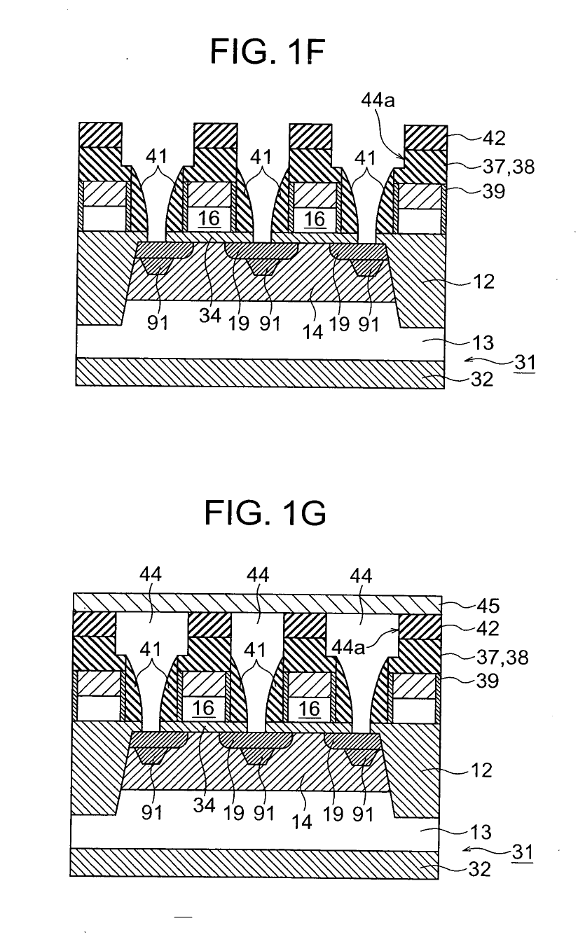

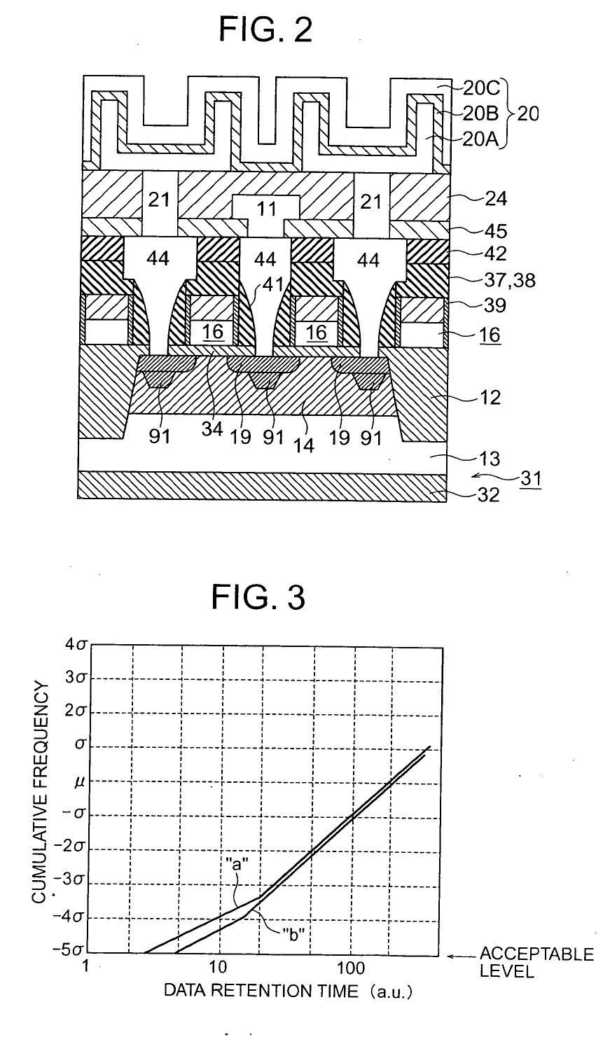

Hereinafter, the present invention will be described in more detail based on preferred embodiments according to the present invention. FIGS. 1A to 1G and FIG. 2 are sectional views respectively showing the steps of manufacturing a semiconductor device according to the first embodiment of the present invention, wherein the present invention is applied to manufacture of cell transistors in a DRAM.

As shown in FIG. 1A, shallow trenches are first formed in the main surface of a silicon substrate 31. Thereafter, an insulating film 12 is filled in the shallow trenches to form shallow-trench isolation regions. Subsequently, a silicon oxide film 33 having a thickness of 10 nm is formed on the substrate surface. Through the silicon oxide film 33, phosphorus implantation is carried out at an acceleration energy of 1000 keV and a dosage of 1×10¹³/cm². Subsequently, a heat treatment is carried out at a substrate temperature of 1000° C. for 10 minutes in a nitrogen ambient, to form an n-type buried well layer 32.

Next, boron implantation is performed four times to form a p-type well layer 13. More specifically, a first-step boron implantation is performed at an acceleration energy of 300 keV and a dosage of 1×10¹³/cm², and thereafter, a heat treatment is carried out at a substrate temperature of 1000° C. for 10 minutes in a nitrogen ambient. Subsequently, a second-step boron implantation is performed also through the silicon oxide film 33 three times at an acceleration energy of 150 keV and a dosage of 5×10¹²/cm², at an acceleration energy of 50 keV and a dosage of 1×10¹²/cm², and at an acceleration energy of 10 keV and a dosage of 2×10¹²/cm², respectively. Thereafter, a second-step heat treatment is carried out at a substrate temperature of 1000° C. for 30 minutes, to form the p-type well layer 13. Thus, in the formation of the p-type well layer 13, the heat treatment is carried out before the total dosage of implantation exceeds 1×10¹³/cm², thereby to reduce residual defects in the implanted region.

Next, as shown in FIG. 1B, boron having a mass number of 10 is selected and implanted at an acceleration energy of 9 keV and a dosage of 7×10¹²/cm². Thereafter, a heat treatment is carried out at a substrate temperature of 1000° C. for 10 seconds in a nitrogen ambient, to form a p-type channel layer 14. Also in formation of the p-type channel layer 14, the number of residual defects in the implanted layer 14 can be reduced by setting the dosage of the single implantation at 1×10¹³/cm² or less and by carrying out a heat treatment subsequent to the implantation. The residual defects in the implanted layer 14 can further be reduced by selecting and implanting boron having a mass number of 10.

Next, as shown in FIG. 1C, the silicon oxide film 33 is removed, and thereafter, a gate oxide film 34 having a thickness of 7 nm is formed by a thermal oxidation process. Subsequently, a polysilicon film 35 having a thickness of 70 nm and heavily-doped with phosphorous, a tungsten silicide film 36 having a thickness of 100 nm, a silicon oxide film 37 having a thickness of 30 nm, and a silicon nitride film 38 having a thickness of 150 nm are consecutively deposited on the gate oxide film 34.

Next, as shown in FIG. 1D, patterning is performed on the silicon nitride film 38, silicon oxide film 37, tungsten silicide film 36, and polysilicon film 35, to obtain gate electrode structures.

Next, as shown in FIG. 1E, a silicon oxide film 39 having a thickness of 10 nm is formed on side surfaces of the polysilicon film 35 and tungsten silicide film 36 which configure gate electrodes 16, by a thermal oxidation process. On the substrate surface during this thermal oxidation process, oxidation is also effected on residues of the gate oxide film 34 remaining after patterning of the gate electrodes 16, so that a silicon oxide film 40 having a thickness of 8 nm is formed.

Next, with the gate electrode structure used as a mask, phosphorus implantation is carried out in a plurality of steps through the silicon oxide film 40 to obtain a needed dosage of 1.8×10¹³/cm², thereby forming n-type lightly-doped diffused regions 19, or source/drain diffused regions of the MOS transistors. More specifically, the formation of n-type lightly-doped diffused regions 19 is carried out as follows. A first-step phosphorus implantation is performed at an acceleration energy of 15 KeV and a dosage of 9×10¹²/cm², and thereafter, a first-step heat treatment is carried out at a substrate temperature of 950° C. for 10 seconds in a nitrogen ambient. Subsequently, a second-step phosphorus implantation is performed at an acceleration energy of 10 KeV and a dosage of 9×10¹²/cm², and thereafter, a second-step heat treatment is carried out at a substrate temperature of 1000° C. for 10 seconds in a nitrogen ambient. In this formation of the n-type lightly-doped diffused regions 19 as well, residual defects in the implanted regions can be reduced by setting the dosage of each step of implantation at 1×10¹³/cm² or below and by carrying out the heat treatment subsequent to the each step of implantation.

Next, source/drain diffused regions of transistors in the peripheral circuits not shown are formed in a known method. Then, a silicon nitride film 41 having a thickness of 50 nm and a silicon oxide film 42 having a thickness of 300 nm are deposited. Subsequently, the silicon oxide film 42 is subjected to planarization by use of a well-known planarization method, and thereafter, the silicon oxide film 42 and silicon nitride film 41 are consecutively etched, to form through-holes 44a as shown in FIG. 1F.

Next, with the silicon oxide film 42 and silicon nitride film 41 used as a mask, phosphorus implantation is carried out at an acceleration energy of 30 KeV and a dosage of 1×10¹³/cm², and thereafter, a heat treatment is carried out at a substrate temperature of 950° C. for 10 seconds in a nitrogen ambient, to form electric-field alleviation regions 91. In this process, in order to allow the electric-field alleviation regions 91 to have a suitable function, residual defects should be avoided as many as possible. However, effective electric-field alleviation can be possibly achieved since the number of residual defects are reduced by the heat treatment described above. Subsequently, arsenic implantation is carried out at an acceleration energy of 20 KeV and a dosage of 2×10^{—}/cm², to reduce the resistance of the n-type lightly-doped diffused regions 19. Since residual defects in an arsenic-implanted layer occur only near the surface of the electric-field alleviation region 91, the heat treatment for the plug formation can sufficiently reduce the residual defects.

Next, as shown in FIG. 1G, a polysilicon film heavily-doped with phosphorous is deposited inside the through-holes 44a and on the silicon oxide film 42. Then, the polysilicon film is etched-back by use of a well-known method, to form plugs 44 buried in the through-holes 44a. Subsequently, a silicon oxide film 45 having a thickness of 100 nm is deposited, and thereafter, a heat treatment is carried out at a substrate temperature of 900° C. for 10 seconds.

Formed next by use of a well-known method are an interlayer dielectric film 24 deposited on the silicon oxide film 45, a bit line 11 formed in the silicon oxide film 45 as well as the interlayer dielectric film 24 and connected to the center plug 44, and plugs 21 connected to the other plugs 44 on both sides of the center plug 44. Subsequently, by use of a well-known method, capacitors 20 each including a bottom electrode 20A connected to the plugs 21, a capacitor insulation film 20B, and a top electrode 20C are formed. Thus, the semiconductor device shown in FIG. 2 is completed.

According to the present embodiment, multi-step implantation is performed to obtain a needed dosage of 3×10¹³/cm² or less in formation of each of implanted regions including the p-type well layer 13, p-type channel layer 14, and the n-type lightly-doped diffused regions 19. The dosage of each step of the implantation is set at 1×10¹³/cm² or less, and a heat treatment is carried out also in a plurality of steps, each subsequent to the each step or a plurality of steps of implantation. Thus, residual defects in each implanted region can be reduced. When forming the p-type channel layer 14, boron having a mass number of 10 is selected and implanted so that residual defects in each implanted region such as the n-type lightly-doped diffused regions 19 and the like can be reduced significantly.

Semiconductor devices were manufactured according to each of the present embodiment and a conventional method for manufacturing a semiconductor device. The thus manufactured semiconductor devices are referred to as Embodiment 1 and Comparative Example 1, respectively. For each of the semiconductor devices of Embodiment 1 and Comparative Example 1, data retention times of memory cells were measured and cumulative frequency was calculated therefrom. FIG. 3 shows the results of the measurements. In the figure, the graph “b” indicates the characteristic of the semiconductor device according to Embodiment 1, whereas the graph “a” indicates the characteristic of the semiconductor device according to Comparative Example 1. Cumulative frequency of −5σ is an acceptable level of products to be shipped. As can be seen from the figure, the semiconductor device according to Embodiment 1 is significantly improved in the data retention characteristic, compared with the semiconductor device according to Comparative Example. It can hence be said that the data retention characteristic of a semiconductor device is generally ruled by the junction leakage current caused by the residual defects.

In the present embodiment, a multi-step implantation associated with a multi-step heat treatment are carried out, wherein the dosage of a single step of the implantation is 1×10¹³/cm² or less for every implanted region which requires a needed dosage of 1×10¹³/cm² or more, to obtain a dosage exceeding 1×10¹³/cm² for the implanted region. However, the multi-step implantation and the multi-step heat treatment need not always be adopted to all the implanted regions. Preferably, the multi-step implantation and multi-step heat treatment as described above should be adopted to form such an implanted region which most effectively improves the characteristic of the semiconductor device. This provides reduction of the number of residual defects while performing suitable heat treatments.

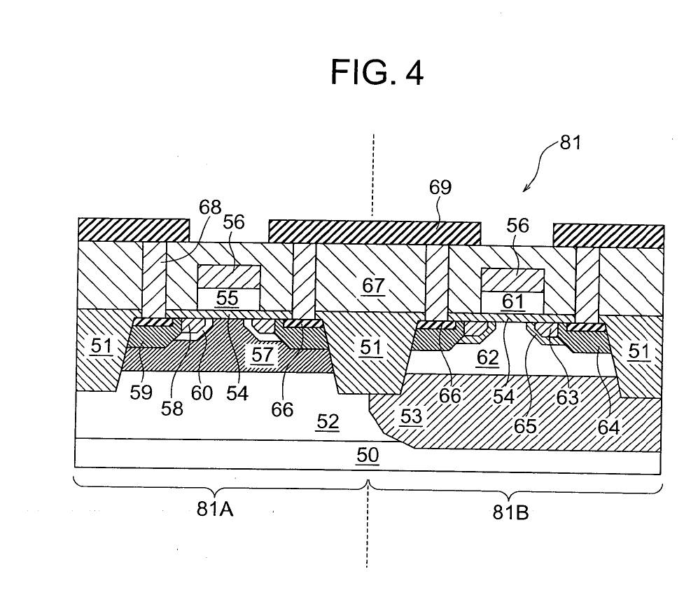

Although the first embodiment has been described with reference to an example in which the present invention is applied to manufacture of cell transistors in a DRAM, the present invention may be also applied to MOS transistors in other devices. FIG. 4 is a sectional view showing the structure of a semiconductor device manufactured by use of a method according to the second embodiment of the present invention. The semiconductor device according to the present embodiment constitutes complementary MOS transistors.

The semiconductor device 81 has an n-channel MOS transistor 81A on the left side of a broken line, and a p-channel MOS transistor 81B on the right side thereof. Those regions of the n-channel MOS transistor 81A and p-channel MOS transistor 81B located in the vicinity of the surface of a substrate 50 are configured by element isolation regions 51, a p-type well layer 52 and an n-type well layer 53, the latter two being electrically separated by the element isolation regions 51.

The n-channel MOS transistor 81A is formed in the top portion of the p-type well layer 52 and has an n-type gate electrode on a gate oxide film 54. The n-type gate electrode is configured by a polysilicon film 55 heavily-doped with phosphorous and an overlying tungsten film 56. A p-type channel layer 57 is formed below the n-type gate electrode with the gate oxide film 54 interposed therebetween. Formed in a surface region of the p-type channel layer 57 are source/drain diffused regions configured by an n-type lightly-doped diffused regions 58 and an n-type heavily-doped diffused regions 59, and a p-type pocket regions 60 formed to surround the n-type lightly-doped diffused regions 58.

The p-channel MOS transistor 81B is formed in the top portion of the n-type well layer 53, and has a p-type gate electrode on the gate oxide film 54. The p-type gate electrode is configured by a polysilicon film 61 heavily-doped with boron and an overlying tungsten film 56. An n-type channel layer 62 is formed below the p-type gate electrode, with the gate oxide film 54 interposed therebetween. Formed in a surface region of the n-type channel layer 62 are source/drain diffused regions configured by a p-type lightly-doped diffused regions 63 and a p-type heavily-doped diffused regions 64, and n-type pocket regions 65 formed to surround the p-type lightly-doped diffused regions 63.

A cobalt silicide layer 66 is selectively formed on the n-type heavily-doped diffused regions 59 and the p-type heavily-doped diffused regions 64. An interlayer dielectric film 67 is formed on the n-channel MOS transistor 81A and the p-channel MOS transistor 81B. The n-channel MOS transistor 81A and p-channel MOS transistor 81B are connected to interconnections 69 formed on the interlayer dielectric film 67, via tungsten plugs 68 formed in through-holes penetrating the interlayer dielectric film 67. A titanium nitride film not shown is formed between the tungsten plugs 68 and the cobalt silicide layer 66.

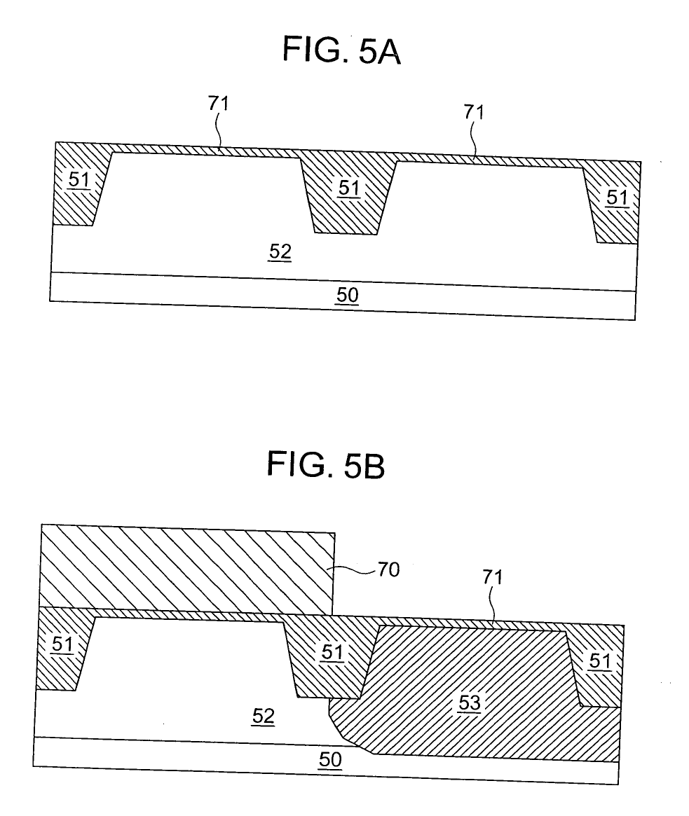

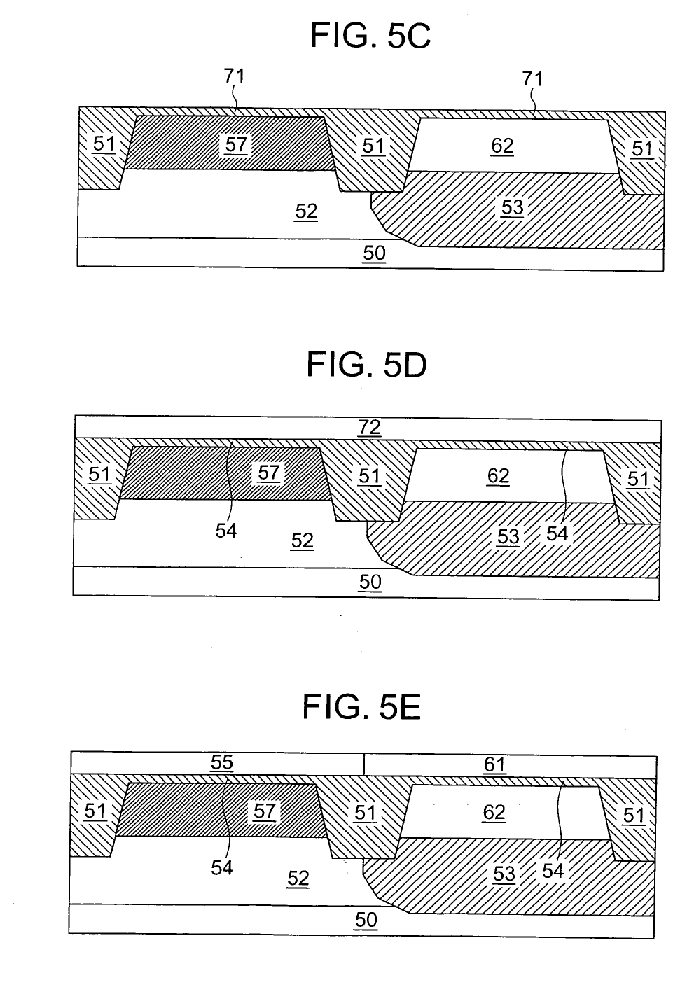

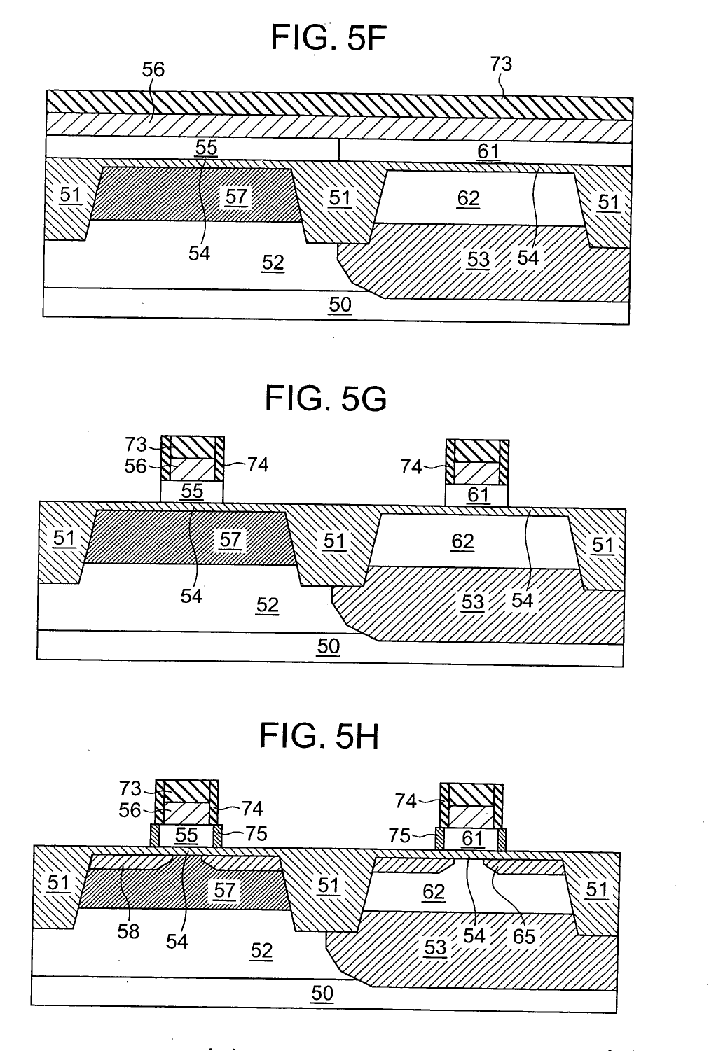

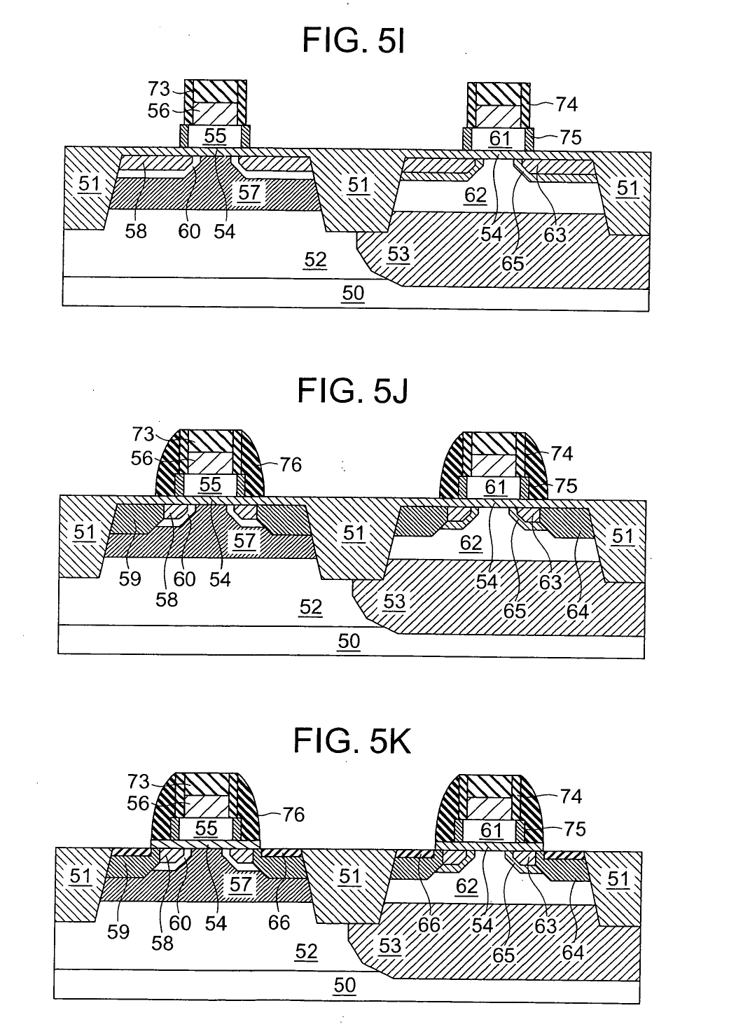

FIGS. 5A to 5K are sectional views respectively showing manufacturing steps in a method for manufacturing a semiconductor device, according to the second embodiment of the present invention. As shown in FIG. 5A, the element isolation regions 51 are first formed by use of a well-known method. Thereafter, a silicon oxide film 71 having a thickness of 10 nm is formed on the surface of the substrate 50.

Next, boron is implanted in three steps through the silicon oxide film 71, to form a p-type well layer 52. More specifically, the p-type well layer 52 is formed by implanting boron in a first-step implantation at an acceleration energy of 300 KeV and a dosage of 1×10¹³/cm² and then carrying out a heat treatment at a substrate temperature of 1000° C. for 10 minutes in a nitrogen ambient. Subsequently, a second-step boron implantation is performed two times, at an acceleration energy of 150 KeV and a dosage of 5×10¹²/cm² and then at an acceleration energy of 50 KeV and a dosage of 1×10¹³/cm². Thereafter, a second-step heat treatment is carried out at a substrate temperature of 1000° C. for 30 minutes. In the formation of the p-type well layer 52, the heat treatments each are carried out at a time point before the implanted amount exceeds 1×10¹³/cm², so that residual defects in the implanted region are reduced.

Next, as shown in FIG. 5B, a resist film 70 patterned so that an area where the p-channel MOS transistor is to be formed has an opening is used as an implantation mask, phosphorus implantation is performed three times through the silicon oxide film 71, at an acceleration energy of 600 KeV and a dosage of 2×10¹³/cm², at an acceleration energy of 330 KeV and a dosage of 1×10¹³/cm², and at an acceleration energy of 130 KeV and a dosage of 2×10¹²/cm², respectively. Subsequently, the resist film 70 is removed, and a heat treatment is carried out once at a substrate temperature of 1000° C. for one minute in a nitrogen ambient, to form the n-type well layer 53. In the n-type well layer 53, an implanted depthwise range of phosphorus is substantially equal to that of boron, and the amount of implanted phosphorus is twice the amount of implanted boron. Therefore, the n-type well layer 53 serves as an n-type layer.

In the above steps of forming the n-type well layer 53, neither a multi-step implantation at a dosage not greater than 1×10¹³/cm² nor a multi-step heat treatment is performed because of the reasons as follows. That is, implantation is performed three times using the same resist film 70. Therefore, deterioration of the resist film 70 may be caused if a multi-step heat treatment is carried out after every implantation. Since phosphorus implantation is performed before boron implantation, it may be considered that a heat treatment can be performed on a phosphorus-implanted region before boron implantation. In this case, phosphorus has greater spread of implantation distribution, which follows a standard deviation of implantation distribution, than boron even if implanted depthwise ranges of boron and phosphorus are substantially equal to each other. Therefore, a distribution profile of phosphorus after a heat treatment cannot be made uniform with that of boron. In the present embodiment, boron implantation and heat treatment thereof are performed prior to phosphorus implantation. Accordingly, the distribution profile of boron can be made substantially uniform with that of phosphorus by redistributing boron by a heat treatment. Note that a multi-step implantation at a dosage of 1×10¹³/cm² or less and a multi-step heat treatment can be performed if the implantation mask is a heat-resistant film.

Next, while a resist film patterned so that an area where the n-channel MOS transistor is to be formed has an opening is used as an implantation mask, boron is implanted through the silicon oxide film 71, at an acceleration energy of 10 KeV and a dosage of 1×10¹²/cm². Subsequently, this resist film is removed, and then, a heat treatment is carried out at a substrate temperature of 1000° C. for 10 seconds in a nitrogen ambient, to form the p-type channel layer 57 as shown in FIG. 5C. Next, while a resist film patterned so that the area where the p-channel MOS transistor is to be formed has an opening is used as an implantation mask, phosphorus is implanted through the silicon oxide film 71, at an acceleration energy of 20 KeV and a dosage of 1×10¹²/cm². Subsequently, this resist film is removed, and then, a heat treatment is carried out at a substrate temperature of 1000° C. for 10 seconds in a nitrogen ambient, to form the n-type channel layer 62.

Next, the silicon oxide film 71 is removed, and then, a gate oxide film 54 having a thickness of 4 nm is formed by a thermal oxidation process, as shown in FIG. 5D. Subsequently, an undoped polysilicon film 72 having a thickness of 100 nm is deposited.

Next, while a resist film not shown patterned so that the area where the n-channel MOS transistor is to be formed has an opening is used as an implantation mask, phosphorus is implanted at an acceleration energy of 10 KeV and a dosage of 5×10¹⁵/cm², to form a polysilicon film 55 heavily-doped with phosphorous, as shown in FIG. 5E. Next, while a resist film not shown patterned so that the area where the p-channel MOS transistor is to be formed has an opening is used as an implantation mask, boron is implanted at an acceleration energy of 5 KeV and a dosage of 3×10¹⁵/cm², to form a polysilicon film 61 doped with boron at a high density.

Next, as shown in FIG. 5F, a tungsten silicide film not shown which has a thickness of 5 nm, a tungsten film 56 having a thickness of 80 nm, and an insulating film 73 for processing gate electrodes are consecutively deposited. Subsequently, as shown in FIG. 5G, the insulating film 73 is patterned by use of a well-known method. Thereafter, the tungsten film 56 and tungsten silicide film are patterned, with the patterned insulating film 73 used as an etching mask. Then, side spacers 74 configured from a silicon nitride film having a thickness of 10 nm are formed on side walls of the tungsten film 56 and tungsten silicide film by use of a well-known method. Thereafter, the polysilicon films 55 and 61 are etched, with the side spacers 74 used as an etching mask.

Next, as shown in FIG. 5H, a silicon oxide film 75 having a thickness of 5 nm is formed on each of side walls of the polysilicon films 55 and 61 by a thermal oxidation process. By this thermal oxidation, those parts of the gate oxide film 54 that still remain after etching the polysilicon films 55 and 61 are oxidized.

Next, phosphorus is implanted at an acceleration energy of 15 KeV and a dosage of 1×10¹³/cm², and thereafter, a heat treatment is carried out at a substrate temperature of 1000° C. for one second in a nitrogen ambient. Subsequently, phosphorus is implanted again at an acceleration energy of 10 KeV and a dosage of 1×10¹³/cm², and thereafter, a heat treatment is carried out at a substrate temperature of 1000° C. for one second in a nitrogen ambient. Thus, a part of the n-type lightly-doped diffused regions 58 in the n-channel MOS transistor and the n-type pocket regions 65 in the p-channel MOS transistor are formed. In the formation of the part of the n-type lightly-doped diffused regions 58 and the n-type pocket regions 65, the dosage in each multi-step implantation is set to 1×10¹³/cm² or less, and a subsequent heat treatment is carried out after each multi-step implantation. Therefore, residual defects in the implanted regions can be reduced.

Next, while a resist film not shown patterned so that the area where the n-channel MOS transistor is to be formed has an opening is used as an implantation mask, boron is implanted at an acceleration energy of 30 KeV and a dosage of 1×10¹³/cm², to form a p-type pocket regions 60, as shown in FIG. 5I. Further, arsenic is implanted at an acceleration energy of 15 KeV and a dosage of 7×10¹³/cm², to form a part of the n-type lightly-doped diffused regions 58. Subsequently, the resist film is removed, and thereafter, a heat treatment is carried out at a substrate temperature of 950° C. for 10 seconds.

Next, side spacers configured from a silicon nitride film 76 having a thickness of 50 nm are formed by a well-known method. Thereafter, arsenic is implanted at an acceleration energy of 50 KeV and a dosage of 2×10¹⁵/cm², to form the n-type heavily-doped diffused regions 59. Further, boron difluoride is implanted at an acceleration energy of 25 KeV and a dosage of 5×10¹⁵/cm², to form the p-type heavily-doped diffused regions 64. Subsequently, a heat treatment is carried out at a substrate temperature of 1000° C. for one second in a nitrogen ambient.

Next, as shown in FIG. 5K, a cobalt silicide layer 66 having a thickness of 30 nm is selectively formed on the n-type heavily-doped diffused regions 59 and the p-type heavily-doped diffused regions 64 by a well-known method. Thereafter, an interlayer dielectric film 67 is deposited. Through-holes are then formed, and tungsten plugs 68 and a an interconnection layer 69 are formed. Thus, the semiconductor device shown in FIG. 4 is manufactured.

According to the present embodiment, the dosage of each step of the implantation is set at 1×10¹³/cm² or less in the process for forming the implanted regions such as p-type well layer 52, p-type channel layer 57, n-type channel layer 62, n-type lightly-doped diffused regions 58, and n-type pocket regions 65, in the manufacture of a semiconductor device including a complementary MOS structure. A heat treatment is carried out subsequent to each implantation. As a result, the residual defects in each implanted region can be reduced.

Semiconductor devices were manufactured in the method according to the present embodiment, and are referred to as Embodiment 2. In addition, Comparative Example 2 was prepared in a manner described below. That is, dopant implantation was performed at a dosage needed for forming each implanted region, and a subsequent single heat treatment is carried out, in place of performing multi-step implantation employing a dosage of 1×10¹³/cm² or less for each step and associated with a multi-step heat treatment, in the process step for forming the p-type well layer 52, p-type channel layer 57, n-type channel layer 62, n-type lightly-doped diffused regions 58, and n-type pocket regions 65, in the method according to the present embodiment.

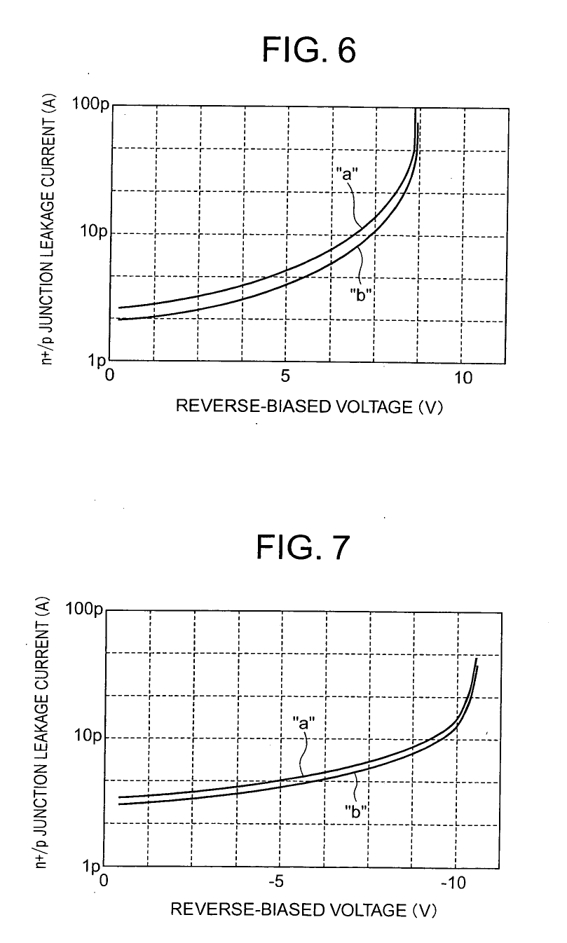

The semiconductor devices of Embodiment 2 and Comparative Example 2 were investigated as to the relationship between the junction leakage current and a reverse-biased voltage in the n-channel MOS transistor and the p-channel MOS transistor. Results of he measurements are respectively shown in FIGS. 6 and 7. In these figures, the graph “a” indicates the characteristic of the semiconductor device of Comparative Example 2, and the graph “b” indicates the characteristic of the semiconductor device of the Embodiment 2. It is understood from these figures that the semiconductor device of Embodiment 2 can reduce the junction leakage current, compared with the semiconductor device of Comparative Example 2.

In the semiconductor device of Embodiment 2, the number of residual defects in the p-type well layer 52, p-type channel layer 57, and n-type lightly-doped diffused regions 58 in the n-channel MOS transistor was found to be reduced to ½ of that of Comparative Example 2. The number of residual defects in the n-type channel layer 62 and n-type pocket regions 65 in the p-channel MOS transistor was found to be reduced by 30%, compared with that of Comparative Example 2. Further, the semiconductor devices of the Embodiment 2 and Comparative Example 2 were applied to an SRAM device having a complementary MOS structure. Then, the semiconductor device of Embodiment 2 could reduce the standby current by 25%, compared with the semiconductor device of Comparative Example 2.

Since the above embodiments are described only for examples, the present invention is not limited to the above embodiments and various modifications or alterations can be easily made therefrom by those skilled in the art without departing from the scope of the present invention.

By applying the method for manufacturing a semiconductor device, according to the present invention, to manufacture of a DRAM, the data retention characteristic of the memory cells in the DRAM can be improved. It is therefore possible to extend the refresh cycle so that electric power consumption consumed by charging and discharging the electronic data can be reduced. Alternatively, when the present invention is applied to manufacture of an SRAM, the standby current is reduced so that electric power consumption is reduced. The present invention is especially preferably applied to manufacture of a semiconductor device for use in a mobile terminal or in a semiconductor device which works at a high temperature.

1. A method for manufacturing a semiconductor device having a MOS transistor, comprising the step of:
implanting a dopant in a specific region or specific layer at a dosage not lower than 1×10¹³/cm² by using a multi-step implantation and an associated multi-step heat treatment, said multi-step implantation including a number of steps of implantation each for implanting said dopant in said specific region or specific layer at a dosage lower than 1×10¹³/cm².

2. The method according to claim 1, wherein there is no step for changing the structure of the semiconductor device between adjacent two steps of said multi-step implantation.

3. The method according to claim 1, wherein a total dosage of said multi-step implantation is not higher than 3×10¹³/cm².

4. The method according to claim 1, wherein each step of said multi-step heat treatment is conducted at a substrate temperature of 900 to 1100 degrees C. for 1 to 60 seconds.

5. The method according to claim 1, wherein said specific region or specific layer is a well layer, channel layer, pocket region or source/drain region.

6. The method according to claim 1, wherein said dopant is phosphorous or boron.

7. A method for manufacturing a semiconductor device having a MOS transistor, comprising the step of:
selecting boron having a mass number of 10 to implant a specific region or layer

8. The method according to claim 7, wherein said specific region or specific layer is a channel layer.
